(19) United States
(12) Patent Application Publication
(10) Pub. No.: US 2024/0421136 A1
(43) Pub. Date: Dec. 19, 2024

(54) SEMICONDUCTOR PACKAGE

(71) Applicant: SAMSUNG ELECTRONICS CO., LTD., SUWON-SI (KR)

(72) Inventor: YOUNGBAE KIM, Suwon-si (KR)

(21) Appl. No.: 18/410,400

(22) Filed: Jan. 11, 2024

(30) Foreign Application Priority Data
Jun. 13, 2023 (KR) 10-2023-0075750

(51) Int. Cl. H01L 25/10; H01L 23/498; H01L 23/538; H10B 80/00

(52) U.S. Cl. CPC H01L 25/105; H01L 23/49816; H01L 23/49822; H01L 23/49838; H01L 23/538; H10B 80/00

(57) ABSTRACT

A semiconductor package includes a package substrate. A first device is on the package substrate. A second device is on the package substrate and is horizontally spaced apart from the first device. The package substrate includes a core portion. A bridge chip is on a top surface of the core portion. The bridge chip has first pads. An upper buildup portion covers the top surface of the core portion and surrounds the bridge chip. The upper buildup portion has second pads. First solders couple the first device to the first pads and second solders couple the first device to the second pads. A first height of the first solders is less than a second height of the second solders. A first interval between adjacent first solders of the first solders is less than a second interval between adjacent second solders of the second solders.

### CROSS-REFERENCE TO RELATED APPLICATION

This application claims priority under 35 U.S.C § 119 to Korean Patent Application No. 10-2023-0075750, filed on Jun. 13, 2023 in the Korean Intellectual Property Office, the disclosure of which is incorporated by reference in its entirety herein.

### 1. TECHNICAL FIELD

Embodiments of the present inventive concept relate to a semiconductor package and a method of fabricating the same.

### 2. DISCUSSION OF RELATED ART

There has been an increased demand for electronic products having high performance, high speed, and a compact size along with the development of electronic industry. To meet these demands, a packaging technology has been developed in which a plurality of semiconductor chips are mounted in a single package.

There has been an increased demand for a reduction in size and weight of electronic parts to provide electronic devices having increased portability. To accomplish the reduction in size and weight of the electronic parts, there is a need for technology to integrate a number of individual devices into a single package as well as technology to reduce individual sizes of mounting parts.

### SUMMARY

Some embodiments of the present inventive concept provide a semiconductor package with increased operating stability.

Some embodiments of the present inventive concept provide a semiconductor package with increased electrical properties.

The objects of the present inventive concept are not necessarily limited to those mentioned above, and other objects which have not been mentioned above will be clearly understood to those skilled in the art from the following description.

According to an embodiment of the present inventive concept, a semiconductor package includes a package substrate. A first device is on the package substrate. A second device is on the package substrate and is horizontally spaced apart from the first device. The package substrate includes a core portion. A bridge chip is on a top surface of the core portion. The bridge chip has first pads. An upper buildup portion covers the top surface of the core portion and surrounds the bridge chip. The upper buildup portion has second pads. First solders couple the first device to the first pads and second solders couple the first device to the second pads. A first height of the first solders is less than a second height of the second solders. A first interval between adjacent first solders of the first solders is less than a second interval between adjacent second solders of the second solders.

According to an embodiment of the present inventive concept, a semiconductor package includes a package substrate. A first device is on the package substrate. A second device is on the package substrate. The second device is horizontally spaced apart from the first device. The package substrate includes a core portion. A bridge chip is on a top surface of the core portion. An upper buildup portion covers the top surface of the core portion and surrounds the bridge chip. The bridge chip includes first pads below the first device and second pads below the second device. The upper buildup portion includes third pads below the first device and fourth pads below the second device. Top surfaces of the first and second pads are positioned at a level higher than a level of top surfaces of the third and fourth pads.

According to an embodiment of the present inventive concept, a semiconductor package includes a substrate. A first semiconductor chip is on the substrate. A chip stack is horizontally spaced apart from the first semiconductor chip on the substrate. The chip stack includes vertically stacked second semiconductor chips. A molding layer is on the substrate. The molding layer surrounds the first semiconductor chip and the chip stack. The substrate includes a core portion. A bridge chip is on a top surface of the core portion. The bridge chip has first pads. An upper buildup portion covers the top surface of the core portion and surrounds the bridge chip. The upper buildup portion has second pads. First connection terminals couple the first semiconductor chips to the first pads and the second pads. Second connection terminals couple the chip stack to the first pads and the second pads. An interval between adjacent first pads of the first pads is less than an interval between adjacent second pads of the second pads. A vertical distance between the first semiconductor chips and the first pads is less than a vertical distance between the first semiconductor chip and the second pads. A vertical distance between the chip stack and the first pads is less than a vertical distance between the chip stack and the second pads.

### BRIEF DESCRIPTION OF DRAWINGS

FIG. 1 illustrates a cross-sectional view showing a semiconductor package according to an embodiment of the present inventive concept.

FIGS. 2 and 3 illustrate enlarged views showing section A of FIG. 1 according to embodiments of the present inventive concept.

FIG. 4 illustrates an enlarged view showing section B of FIG. 1 according to an embodiment of the present inventive concept.

FIG. 5 illustrates a cross-sectional view showing a semiconductor package according to an embodiment of the present inventive concept.

FIG. 6 illustrates an enlarged view showing section C of FIG. 5 according to an embodiment of the present inventive concept.

FIG. 7 illustrates a cross-sectional view showing a semiconductor package according to an embodiment of the present inventive concept.

FIG. 8 illustrates an enlarged view showing section D of FIG. 7 according to an embodiment of the present inventive concept.

FIG. 9 illustrates a cross-sectional view showing a semiconductor package according to an embodiment of the present inventive concept.

FIG. 10 illustrates an enlarged view showing section E of FIG. 9 according to an embodiment of the present inventive concept.

FIG. 11 illustrates a cross-sectional view showing a semiconductor module according to an embodiment of the present inventive concept.

FIGS. 12 to 18 illustrate cross-sectional views showing a method of fabricating a semiconductor package according to some embodiments of the present inventive concept.

### DETAILED DESCRIPTION OF EMBODIMENTS

The following will now describe a semiconductor package according to an embodiment of the present inventive concept with reference to the accompanying drawings.

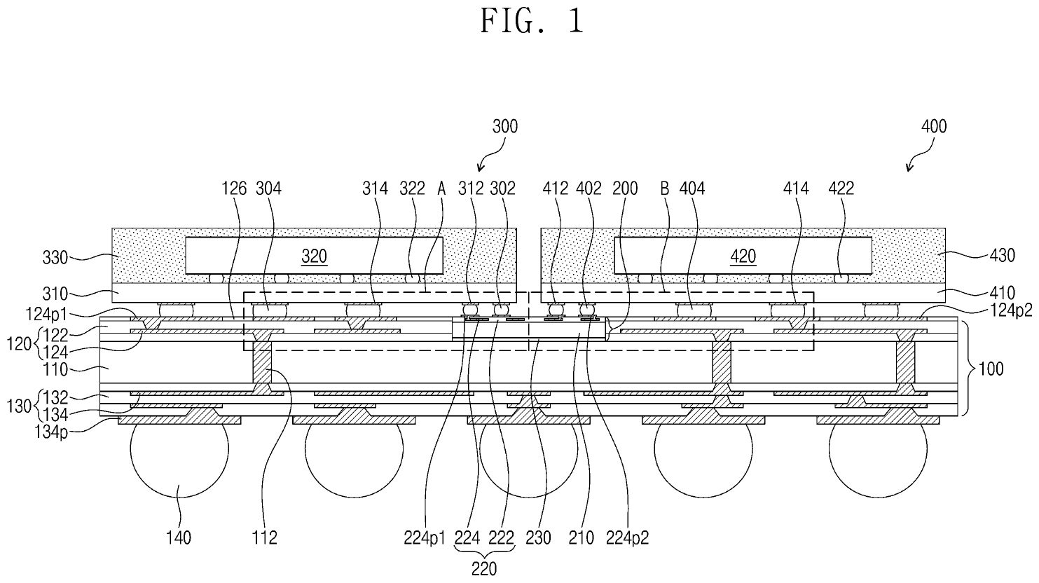

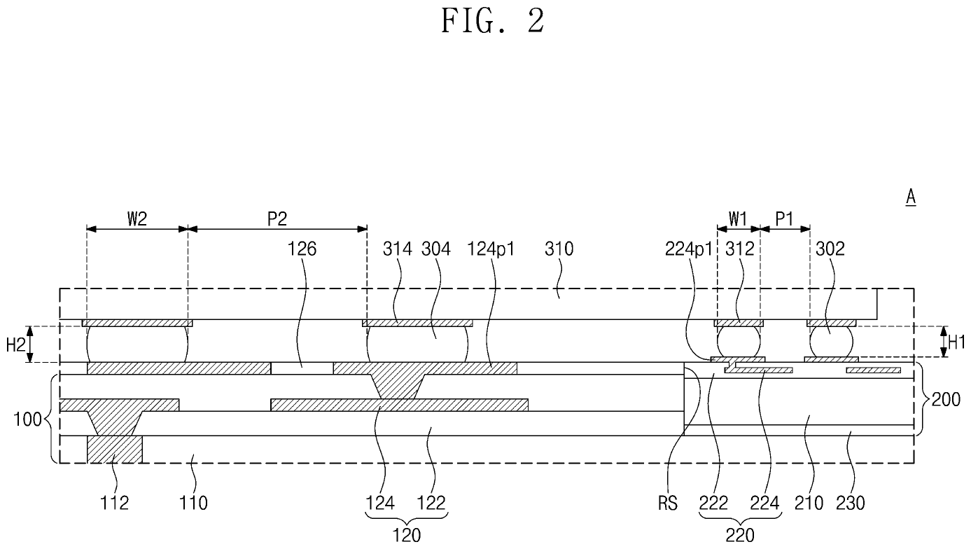

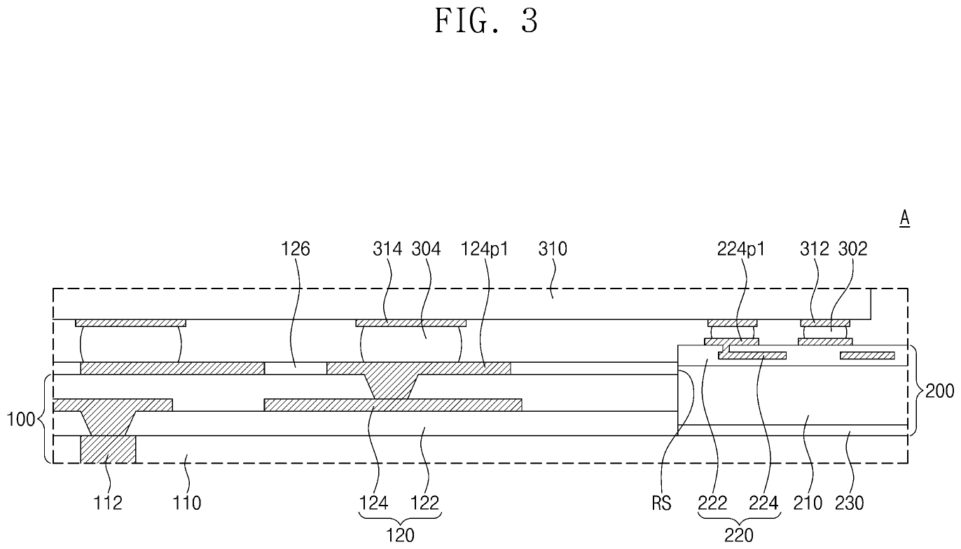

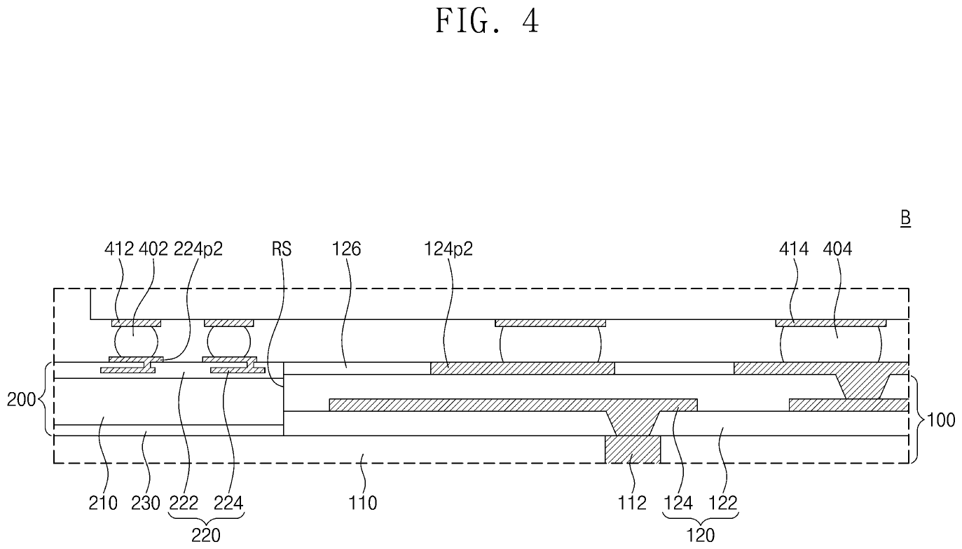

FIG. 1 illustrates a cross-sectional view showing a semiconductor package according to some embodiments of the present inventive concept. FIGS. 2 and 3 illustrate enlarged views showing section A of FIG. 1. FIG. 4 illustrates an enlarged view showing section B of FIG. 1.

Referring to FIG. 1, a package substrate 100 may be provided. The package substrate 100 may include a core portion 110, an upper buildup portion 120 disposed on a top surface of the core portion 110, and a lower buildup portion 130 disposed on a bottom surface of the core portion 110.

The core portion 110 may extend in one direction. When viewed in plan, the core portion 110 may include a single core pattern. Although the core portion 110 having a single core pattern is discussed by way of example, embodiments of the present inventive concept are not necessarily limited thereto. According to some embodiments, the core portion 110 may include two or more core patterns. For example, in an embodiment the package substrate 100 may include a plurality of core patterns that are spaced apart from each other when viewed in plan. The core portion 110 may include a dielectric material. For example, in an embodiment the core portion 110 may include one of glass fibers, ceramic plates, epoxy, and resins. In another example, the core portion 110 may include one selected from stainless steels, aluminum (Al), nickel (Ni), magnesium (Mg), zinc (Zn), tantalum (Ta), and any combination thereof.

The core portion 110 may include first vertical connection terminals 112 that vertically penetrate the core portion 110. The first vertical connection terminals 112 may extend from the bottom surface of the core portion 110 towards the top surface of the core portion 110. In an embodiment, the first vertical connection terminals 112 may be exposed on the bottom surface of the core portion 110 and the top surface of the core portion 110. The first vertical connection terminals 112 may electrically connect to each other the upper buildup portion 120 and the lower buildup portion 130 which will be discussed below. In an embodiment, the first vertical connection terminals 112 may include a metallic material, such as copper (Cu) or tungsten (W).

The lower buildup portion 130 may be disposed on the bottom surface of the core portion 110. The lower buildup portion 130 may cover the bottom surface of the core portion 110. The lower buildup portion 130 may include one or more first wiring layers that are sequentially stacked on the bottom surface of the core portion 110. Each first wiring layer may include a lower dielectric pattern 132 and a lower wiring pattern 134 in the lower dielectric pattern 132. In an embodiment, the lower wiring pattern 134 of one first wiring layer may be electrically connected to the lower wiring pattern 134 of another adjacent first wiring layer.

In an embodiment, the lower dielectric pattern 132 may include prepreg, Ajinomoto build-up film (ABF), flame retardant 4 (FR-4), or bismaleimide triazine (BT).

The lower wiring patterns 134 may include a circuit pattern. The lower wiring pattern 134 may be disposed on the lower dielectric pattern 132. For example, in an embodiment, the lower wiring pattern 134 may be disposed on a bottom surface of the lower dielectric pattern 132. The lower wiring pattern 134 may protrude onto the bottom surface of the lower dielectric pattern 132. The lower wiring pattern 134 may extend horizontally on the bottom surface of the lower dielectric pattern 132. Below the lower dielectric pattern 132, the lower wiring pattern 134 may be covered with an underlying other lower dielectric pattern 132. As such, the lower wiring pattern 134 may be a pad or line part of the first wiring layer. The lower wiring pattern 134 may include a conductive material. For example, in an embodiment the lower wiring pattern 134 may include at least one selected from copper (Cu), aluminum (Al), silver (Ag), tin (Sn), gold (Au), nickel (Ni), lead (Pb), titanium (Ti), and any combination thereof.

In an embodiment, the lower wiring pattern 134 may have a damascene structure. For example, the lower wiring pattern 134 may have a via that protrudes onto a top surface thereof. The via may be a component for vertical connection between the lower wiring patterns 134 of adjacent first wiring layers. For example, in an embodiment the via may extend from the top surface of the lower wiring pattern 134 through the lower dielectric pattern 132 to be coupled to the lower wiring pattern 134 of an overlying adjacent first wiring layer. A lower portion of the lower wiring pattern 134 disposed below the lower dielectric pattern 132 may be a head part used as a horizontal wiring line or pad, and the via of the lower wiring pattern 134 may be a tail part. The lower wiring pattern 134 may have an inverse T shape.

A plurality of external terminals 140 may be disposed below the lower buildup portion 130. The external terminals 140 may be disposed on a bottom surface of the lower buildup portion 130. For example, in an embodiment the external terminals 140 may be disposed on external substrate pads 134p disposed on the bottom surface of the lower buildup portion 130. In this embodiment, the external substrate pads 134p may be either portions of the lower wiring patterns 134 exposed from the lower dielectric patterns 132 of the lower buildup portion 130 or separate pads that are disposed on the lower dielectric patterns 132 of the lower buildup portion 130 to come into connection with the lower wiring patterns 134. In an embodiment, the external terminals 140 may include solder balls or solder bumps.

The upper buildup portion 120 may be disposed on the top surface of the core portion 110. The upper buildup portion 120 may cover the top surface of the core portion 110. The upper buildup portion 120 may include one or more second wiring layers that are sequentially stacked on the top surface of the core portion 110. In an embodiment, each second wiring layer may include an upper dielectric pattern 122 and an upper wiring pattern 124 in the upper dielectric pattern 122. The upper wiring pattern 124 of a one second wiring layer may be electrically connected to the upper wiring pattern 124 of an adjacent second wiring layer.

In an embodiment, the upper dielectric pattern 122 may include prepreg, Ajinomoto buildup film (ABF), flame retardant 4 (FR-4), or bismaleimide triazine (BT).

The upper wiring pattern 124 may include a circuit pattern. The upper wiring pattern 124 may be disposed on the upper dielectric pattern 122. The upper wiring pattern 124 may be disposed on a top surface of the upper dielectric pattern 122. The upper wiring pattern 124 may protrude onto the top surface of the upper dielectric pattern 122. The upper wiring pattern 124 may extend horizontally on the top surface of the upper dielectric pattern 122. In an embodiment, on the upper dielectric pattern 122, the upper wiring pattern 124 may be covered with an overlying upper dielectric pattern 122. The upper wiring pattern disposed on an uppermost second wiring layer may serve as a substrate pad to which first and second devices 300 and 400 are coupled as discussed below. For example, portions of the upper wiring pattern disposed on an uppermost second wiring layer may be first substrate pads 124p1 to which the first device 300 is coupled. Other portions of the upper wiring pattern disposed on an uppermost second wiring layer may be second substrate pads 124p2 to which the second device 400 is coupled. As such, the upper wiring pattern 124 may be a pad or line part of the second wiring layer. The upper wiring pattern 124 may include a conductive material. For example, in an embodiment the upper wiring pattern 124 may include at least one selected from copper (Cu), aluminum (Al), silver (Ag), tin (Sn), gold (Au), nickel (Ni), lead (Pb), titanium (Ti), and any combination thereof.

The upper wiring pattern 124 may have a damascene structure. For example, the upper wiring pattern 124 may have a via that protrudes onto a bottom surface thereof. The via may be a component for vertical connection between the upper wiring patterns 124 of adjacent second wiring layers. For example, the via may extend from the bottom surface of the upper wiring pattern 124 through the upper dielectric pattern 122 to be coupled to a top surface of the upper wiring pattern 124 of an underlying second wiring layer. In an embodiment, an upper portion of the upper wiring pattern 124 disposed on the upper dielectric pattern 122 may be a head part used as a horizontal wiring line or pad, and the via of the upper wiring pattern 124 may be a tail part. The upper wiring pattern 124 may have a T shape.

A substrate protection layer 126 may be provided on the upper buildup portion 120. The substrate protection layer 126 may cover the uppermost second wiring layer. The substrate protection layer 126 may surround the first and second substrate pads 124p1 and 124p2, while covering the upper dielectric pattern 122. The first and second substrate pads 124p1 and 124p2 may be exposed on a top surface of the substrate protection layer 126. In an embodiment, the substrate protection layer 126 may include a dielectric polymer or a photo-imageable dielectric. In some embodiments, the substrate protection layer 126 may be omitted.

The upper buildup portion 120 may have a recess (see RS of FIG. 2). For example, in an embodiment the recess RS may be shaped like an open hole that connects top and bottom surfaces of the upper buildup portion 120. The recess RS may vertically penetrate the upper dielectric patterns 122 of the upper buildup portion 120. In an embodiment in which the substrate protection layer 126 is disposed on the upper buildup portion 120, the recess RS may vertically penetrate the substrate protection layer 126 and the upper buildup portion 120. The recess RS may penetrate the upper buildup portion 120 to expose the top surface of the core portion 110. In an embodiment, the recess RS may be positioned at a central portion of the upper buildup portion 120. In comparison to the recess RS, the upper wiring patterns 124 of the upper buildup portion 120 may be positioned on an outer side of the upper buildup portion 120. The first vertical connection terminals 112 of the core portion 110 may not be disposed below the recess RS.

A bridge chip 200 may be disposed on the package substrate 100. For example, in an embodiment the bridge chip 200 may be provided as a portion of the package substrate 100. However, embodiments of the present disclosure are not necessarily limited thereto. For convenience of description, the package substrate 100 and the bridge chip 200 will be treated as individual elements in the present embodiment. The bridge chip 200 may be disposed in the recess RS. In an embodiment, the bridge chip 200 may fill an entirety of the recess RS. For example, the bridge chip 200 may be in direct contact with the top surface of the core portion 110 exposed by the recess RS. In an embodiment, the bridge chip 200 may be in contact with an inner sidewall of the recess RS or an inner lateral surface of the upper buildup portion 120. When viewed in plan, the upper buildup portion 120 may completely surround lateral sides of the bridge chip 200. A top surface of the bridge chip 200 may be exposed from a top surface of the upper buildup portion 120. In an embodiment, the bridge chip 200 may have a thickness that is greater than that of the upper buildup portion 120. This will be further discussed in detail below.

The bridge chip 200 may have a front surface and a rear surface. In the present description, the term “front surface” may be defined to indicate an active surface of an integrated element in a semiconductor chip, a surface on which wiring lines are formed, or a surface on which pads of a semiconductor chip are formed, and the term “rear surface” may be defined to indicate a surface opposite to the front surface. The rear surface of the bridge chip 200 may face the core portion 110. For example, in an embodiment the bridge chip 200 may be disposed in a face-up manner on the core portion 110. In an embodiment, the bridge chip 200 may be attached through an adhesion layer 230 to the core portion 110. For example, the adhesion layer 230 may be interposed between a bottom surface of the bridge chip 200 and the top surface of the core portion 110. The first vertical connection terminals 112 of the core portion 110 may not be disposed below the bridge chip 200. In an embodiment, the bridge chip 200 may include a bridge base layer 210 and a bridge wiring layer 220.

In an embodiment, the bridge base layer 210 may include a semiconductor substrate. For example, the bridge base layer 210 may be a semiconductor substrate, such as a semiconductor wafer. In an embodiment, the bridge base layer 210 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). The bridge base layer 210 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

A bridge wiring layer 220 may be disposed on a top surface of the bridge base layer 210. For example, in an embodiment the bridge wiring layer 220 may include a bridge dielectric pattern 222 and a bridge wiring pattern 224 that are formed on the top surface of the bridge base layer 210. In some embodiments, the bridge wiring layer 220 may further include a circuit pattern or a protection layer.

The bridge dielectric pattern 222 may include a dielectric material. For example, in an embodiment the bridge dielectric pattern 222 may include silicon oxide (SiO), silicon nitride (SiN), silicon oxynitride (SiON), silicon carbonitride (SiCN), or dielectric polymer materials. Alternatively, the bridge dielectric pattern 222 may include a dielectric polymer or a photo-imageable dielectric (PID). The photo-imageable dielectric may include, for example, at least one selected from photosensitive polyimide, polybenzoxazole, phenolic polymers, and benzocyclobutene polymers.

The bridge wiring pattern 224 may be disposed in the bridge dielectric pattern 222. The bridge wiring pattern 224 may be a component for electrical connection between the first device 300 and the second device 400. The bridge wiring pattern 224 may include a conductive material. For example, in an embodiment the bridge wiring pattern 224 may include copper (Cu) or aluminum (Al).

FIG. 1 depicts that the bridge dielectric pattern 222 is one layer. However, embodiments of the present inventive concept are not necessarily limited thereto. The bridge dielectric pattern 222 may include a plurality of dielectric layers, and the bridge wiring pattern 224 may be a wiring pattern disposed in the plurality of dielectric layers.

Referring to FIGS. 1 and 2, in an embodiment the bridge wiring layer 220 may have a top surface located at a level the same as that of the top surface of the upper buildup portion 120. In this description, the top surface of the upper buildup portion 120 may correspond to the top surface of the uppermost second wiring layer of the upper buildup portion 120, or top surfaces of the first and second substrate pads 124p1 and 124p2. Alternatively, as shown in FIG. 3, the top surface of the bridge wiring layer 220 may be located at a level higher than that of the top surface of the upper buildup portion 120. For example, the bridge chip 200 may protrude onto the top surface of the upper buildup portion 120. The following description will focus on the embodiment of FIG. 2 for convenience of explanation.

Referring still to FIG. 1, the bridge chip 200 may include first bridge pads 224p1 and second bridge pads 224p2 that are disposed on a top surface of the bridge chip 200. The first and second bridge pads 224p1 and 224p2 may be disposed on the top surface of the bridge chip 200 or the top surface of the bridge wiring layer 220. The first and second bridge pads 224p1 and 224p2 may protrude onto the top surface of the bridge chip 200 However, embodiments of the present inventive concept are not necessarily limited thereto. For example, in some embodiments the first and second bridge pads 224p1 and 224p2 may be portions of the bridge wiring pattern 224 and may be disposed in the bridge dielectric pattern 222. In this embodiment, the first and second bridge pads 224p1 and 224p2 may be exposed on a top surface of the bridge dielectric pattern 222. The first bridge pads 224p1 and the second bridge pads 224p2 may be disposed on different areas of the bridge chip 200. For example, the first bridge pads 224p1 may be disposed adjacent to the first substrate pads 124p1, and the second bridge pads 224p2 may be disposed adjacent to the second substrate pads 124p2.

In an embodiment, the first bridge pads 224p1 may be pads electrically connected to the first device 300, and the second bridge pads 224p2 may be pads electrically connected to the second device 400. For example, the first bridge pads 224p1 may be electrically connected through the bridge wiring layer 220 to the second bridge pads 224p2. FIG. 1 depicts only a portion of the bridge wiring pattern 224, and the first bridge pads 224p1 and the second bridge pads 224p2 may not be electrically insulated from each other in the bridge wiring layer 220. The first bridge pads 224p1 may be electrically connected to the second bridge pads 224p2 through the bridge wiring pattern 224 disposed in the bridge wiring layer 220.

Referring again to FIGS. 1 and 2, top surfaces of the first and second bridge pads 224p1 and 224p2 may be located at a level higher than that of the top surfaces of the first and second substrate pads 124p1 and 124p2. Therefore, a thickness of the bridge chip 200 or a distance between from a bottom surface of the adhesion layer 230 to the top surfaces of the first and second bridge pads 224p1 and 224p2 may be greater than a thickness of the upper buildup portion 120 (e.g., in a vertical direction) or a distance from a bottom surface of a lowermost second wiring layer to the top surfaces of the first and second substrate pads 124p1 and 124p2 (e.g., in the vertical direction). For example, the first bridge pads 224p1 may be closer than the first substrate pads 124p1 to the first device 300 which will be discussed below, and the second bridge pads 224p2 may be closer than the second substrate pads 124p2 to the second device 400 which will be discussed below.

In an embodiment, a wiring density of the bridge chip 200 may be greater than that in the upper buildup portion 120 of the package substrate 100. The integration of the first and second bridge pads 224p1 and 224p2 may be greater than that of the first and second substrate pads 124p1 and 124p2. For example, a first interval PI between the first bridge pads 224p1 may be less than a second interval P2 between the first substrate pads 124p1. An interval between the second bridge pads 224p2 may be less than that between the second substrate pads 124p2. For example, a first width W1 (e.g., length in a horizontal direction) of the first bridge pads 224p1 may be less than a second width W2 (e.g., length in a horizontal direction) of the first substrate pad 124p1. A width of the second bridge pad 224p2 may be less than that of the second substrate pad 124p2. Therefore, an arrangement period of the first and second bridge pads 224p1 and 224p2 may be less than that of the first and second substrate pads 124p1 and 124p2. In an embodiment, the number of the first and second bridge pads 224p1 and 224p2 provided per unit area may be greater than the number of the first and second substrate pads 124p1 and 124p2 provided per unit area.

According to some embodiments of the present inventive concept, an electrical connection through the bridge chip 200 may be provided on an area where a wiring connection with high integration is required, and an electrical connection through the upper buildup portion 120 may be provided on an area where a wiring connection with low integration is required. It may thus be possible to provide the package substrate 100 having high integration and a semiconductor package including the same. In addition, as the bridge chip 200 may be used only on an area requiring high integration, a semiconductor package may have a decreased manufacturing cost.

Referring back to FIG. 1, the first device 300 may be disposed on the package substrate 100. The first device 300 may be a semiconductor package. For example, in an embodiment the first device 300 may include a first substrate 310, a first semiconductor chip 320, and a first molding layer 330.

In an embodiment the first substrate 310 may be a printed circuit board (PCB). Alternatively, the first substrate 310 may be a redistribution layer. The first substrate 310 may include first and second device pads 312 and 314 disposed on (e.g., disposed directly thereon) a bottom surface of the first substrate 310. The first and second device pads 312 and 314 may be electrically connected to the first substrate 310. The first device pads 312 may be disposed between the first substrate 310 and the bridge chip 200. For example, the first device pads 312 may be disposed on the bottom surface of the first substrate 310. The bottom surface of the first substrate 310 is directed towards the first bridge pads 224p1. The second device pads 314 may be disposed between the first substrate 310 and the upper buildup portion 120. For example, the second device pads 314 may be disposed on the bottom surface of the first substrate 310. The bottom surface of the first substrate 310 is directed towards the first substrate pads 124p1. In an embodiment, the first device pads 312 may have bottom surfaces located at a level the same as that of bottom surfaces of the second device pads 314. The integration of the first device pads 312 may be greater than that of the second device pads 314. For example, the first device pads 312 may have a width and interval that are less than those of the second device pads 314. The first device pads 312 may be pads on an area having a wiring density that is high in the first substrate 310, and the second device pads 314 may be pads on an area having a wiring density that is low in the first substrate 310. The first device pads 312 may be electrically connected to the first bridge pads 224p1 of the bridge chip 200, and the second device pads 314 may be electrically connected to the first substrate pads 124p1.

The bottom surface of the first substrate 310 may be substantially parallel to the top surface of the upper buildup portion 120 or the top surface of the bridge chip 200. Since the first bridge pads 224p1 are located at a level higher than that of the first substrate pads 124p1, a first interval H1 (e.g., a first distance in the vertical direction) between the first bridge pads 224p1 and the first device pads 312 may be less than a second interval H2 (e.g., a second distance in the vertical direction) between the first substrate pads 124p1 and the second device pads 314.

The first semiconductor chip 320 may be disposed on the first substrate 310. The first semiconductor chip 320 may include integrated circuits. In an embodiment, the integrated circuits may include a memory circuit, a logic circuit, or a combination thereof. For example, the first semiconductor chip 320 may be a logic chip or a memory chip.

The first semiconductor chip 320 may be provided with first chip terminals 322 on a bottom surface thereof. The first chip terminals 322 may be electrically connected to the integrated circuits of the first semiconductor chip 320.

The first semiconductor chip 320 may be mounted on the first substrate 310. For example, the first semiconductor chip 320 may be coupled through the first chip terminals 322 to pads of the first substrate 310. The first chip terminals 322 may be disposed between the pads of the first substrate 310 and chip pads of the first semiconductor chip 320. FIG. 1 depicts that the first semiconductor chip 320 is flip-chip mounted on the first substrate 310. However, embodiments of the present inventive concept are not necessarily limited thereto. For example, the first semiconductor chip 320 may be wire-bonding mounted on the first substrate 310.

The first substrate 310 may be have a first molding layer 330 disposed thereon that covers the first semiconductor chip 320. In an embodiment, the first molding layer 330 may include a dielectric polymer, such as an epoxy-based polymer.

FIG. 1 depicts that first device 300 is a semiconductor package having one semiconductor chip. However, embodiments of the present inventive concept are not necessarily limited thereto. For example, in an embodiment the first device 300 may be a semiconductor package having a plurality of semiconductor chips. Alternatively, the first device 300 may be one semiconductor chip or one semiconductor die. Alternatively, the first device 300 may include various elements, such as an external connector, an input/output component, or a substrate.

Referring again to FIGS. 1 and 2, the first device 300 may be mounted on the package substrate 100 and the bridge chip 200. For example, in an embodiment the first device 300 may be flip-chip mounted on the package substrate 100 and the bridge chip 200. The first device 300 may be electrically connected through first and second connection terminals 302 and 304 (e.g., first and second solders) to the package substrate 100 and the bridge chip 200. The first connection terminals 302 may be disposed between the first bridge pads 224p1 and the first device pads 312. The second connection terminals 304 may be disposed between the first substrate pads 124p1 and the second device pads 314. The first device 300 may be electrically connected to the bridge chip 200 through the first device pads 312, the first connection terminals 302, and the first bridge pads 224p1, and may be electrically connected to the package substrate 100 through the second device pads 314, the second connection terminals 304, and the first substrate pads 124p1. Based on size and arrangement of the first and second device pads 312 and 314, the first connection terminals 302 may have a width and an interval that is less than those of the second connection terminals 304.

As the first device 300 is mounted through the first and second connection terminals 302 and 304, the first device 300 may be spaced apart from a top surface of the package substrate 100 and the top surface of the bridge chip 200. The first interval H1 between the first bridge pads 224p1 and the first device pads 312 may be less than the second interval H2 between the first substrate pads 124p1 and the second device pads 314. Therefore, a first height of the first connection terminals 302 (e.g., in the vertical direction) may be less than a second height of the second connection terminals 304 (e.g., in the vertical direction).

According to some embodiments of the present inventive concept, an electrical connection through the bridge chip 200 may be provided on an area where a wiring connection with a high integration is required, and an electrical connection through the upper buildup portion 120 may be provided on an area where a wiring connection with low integration is required. A size of the first connection terminals 302 coupled to the first bridge pads 224p1 with high integration may be less than that of the second connection terminals 304 coupled to the first substrate pads 124p1 with low integration. As the first interval H1 between the first bridge pads 224p1 and the first device pads 312 is less than the second interval H2 between the first substrate pads 124p1 and the second device pads 314, the first bridge pads 224p1 and the first device pads 312 may be connected even through the first connection terminals 302 having sizes that are relatively small. For example, although the second connection terminals 304 having a large size are provided between the package substrate 100 and the first device 300, a small interval may be provided between the bridge chip 200 and the first device 300, and no electrical short may occur between the first connection terminals 302 and the first bridge pads 224p1 and between the first connection terminals 302 and the first device pads 312. Accordingly, a semiconductor package may increase in electrical properties and operating stability.

Referring now to FIG. 1, the second device 400 may be disposed on the package substrate 100. On the package substrate 100, the second device 400 may be disposed to be horizontally spaced apart from the first device 300. In an embodiment, the second device 400 may be a semiconductor package. For example, in an embodiment the second device 400 may include a second substrate 410, a second semiconductor chip 420, and a second molding layer 430.

In an embodiment, the second substrate 410 may be a printed circuit board (PCB). Alternatively, the second substrate 410 may be a redistribution layer. In an embodiment, the second substrate 410 may include third and fourth device pads 412 and 414 disposed on (e.g., disposed directly thereon) a bottom surface of the second substrate 410. The third and fourth device pads 412 and 414 may be electrically connected to the second substrate 410. The third device pads 412 may be disposed between the second substrate 410 and the bridge chip 200. For example, the third device pads 412 may be disposed on (e.g., disposed directly thereon) the bottom surface of the second substrate 410. The bottom surface of the second substrate 410 is directed towards the second bridge pads 224p2. The fourth device pads 414 may be disposed between the second substrate 410 and the upper buildup portion 120. For example, the fourth device pads 414 may be disposed on (e.g., disposed directly thereon) the bottom surface of the second substrate 410. The bottom surface of the second substrate 410 is directed towards the second substrate pads 124p2. The third device pads 412 may have bottom surfaces located at a level that is the same as that of bottom surfaces of the fourth device pads 414. The integration of the third device pads 412 may be greater than that of the fourth device pads 414. For example, the third device pads 412 may have a width and an interval that are less than those of the fourth device pads 414. The third device pads 412 may be pads on an area having a high wiring in the second substrate 410, and the fourth device pads 414 may be pads on an area having low wiring density in the second substrate 410. The third device pads 412 may be electrically connected to the second bridge pads 224p2 of the bridge chip 200, and the fourth device pads 414 may be electrically connected to the second substrate pads 124p2.

In an embodiment, the bottom surface of the second substrate 410 may be substantially parallel to the top surface of the upper buildup portion 120 or the top surface of the bridge chip 200. As the second bridge pads 224p2 are located at a level higher than that of the second substrate pads 124p2, an interval between the second bridge pads 224p2 and the third device pads 412 may be less than an interval between the second substrate pads 124p2 and the fourth device pads 414.

The second semiconductor chip 420 may be disposed on the second substrate 410. In an embodiment, the second semiconductor chip 420 may include integrated circuits, and the integrated circuits may include a memory circuit, a logic circuit, or a combination thereof. For example, the second semiconductor chip 420 may be a logic chip or a memory chip.

The second semiconductor chip 420 may be provided with second chip terminals 422 on a bottom surface thereof. The second chip terminals 422 may be electrically connected to the integrated circuits of the second semiconductor chip 420.

The second semiconductor chip 420 may be mounted on the second substrate 410. For example, the second semiconductor chip 420 may be coupled through the second chip terminals 422 to pads of the second substrate 410. The second chip terminals 422 may be disposed between the pads of the second substrate 410 and chip pads of the second semiconductor chip 420. FIG. 1 depicts that the second semiconductor chip 420 is flip-chip mounted on the second substrate 410. However, embodiments of the present inventive concept are not necessarily limited thereto. For example, in an embodiment the second semiconductor chip 420 may be wire-bonding mounted on the second substrate 410.

The second substrate 410 may have a second molding layer 430 disposed thereon that covers the second semiconductor chip 420. In an embodiment, the second molding layer 430 may include a dielectric polymer such as an epoxy-based polymer.

FIG. 1 depicts that second device 400 is a semiconductor package having one semiconductor chip. However, embodiments of the present inventive concept are not necessarily limited thereto. In some embodiments, the second device 400 may be a semiconductor package having a plurality of semiconductor chips. Alternatively, the second device 400 may be one semiconductor chip or one semiconductor die. Alternatively, the second device 400 may include various elements, such as an external connector, an input/output component, or a substrate.

Referring again to FIGS. 1 and 4, the second device 400 may be mounted on the package substrate 100 and the bridge chip 200. For example, in an embodiment the second device 400 may be flip-chip mounted on the package substrate 100 and the bridge chip 200. The second device 400 may be electrically connected through third and fourth connection terminals 402 and 404 to the package substrate 100 and the bridge chip 200. The third connection terminals 402 may be disposed between the second bridge pads 224p2 and the third device pads 412. The fourth connection terminals 404 may be disposed between the second substrate pads 124p2 and the fourth device pads 414. The second device 400 may be electrically connected to the bridge chip 200 through the third device pads 412, the third connection terminals 402, and the second bridge pads 224p2, and may be electrically connected to the package substrate 100 through the fourth device pads 414, the fourth connection terminals 404, and the second substrate pads 124p2. Based on the size and arrangement of the third and fourth device pads 412 and 414, the third connection terminals 402 may have a width and an interval that are less than those of the fourth connection terminals 404.

As the second device 400 is mounted through the third and fourth connection terminals 402 and 404, the second device 400 may be spaced apart from the top surface of the package substrate 100 and the top surface of the bridge chip 200. In an embodiment, the interval between the second bridge pads 224p2 and the third device pads 412 may be less than the interval between the second substrate pads 124p2 and the fourth device pads 414. Therefore, a height of the third connection terminals 402 may be less than that of the fourth connection terminals 404.

According to some embodiments of the present inventive concept, a size of the third connection terminals 402 coupled to the second bridge pads 224p2 with high integration may be less than that of the fourth connection terminals 404 coupled to the second substrate pads 124p2 with low integration. As the interval between the second bridge pads 224p2 and the third device pads 412 is less than that between the second substrate pads 124p2 and the fourth device pads 414, the second bridge pads 224p2 and the third device pads 412 may be connected even through the third connection terminals 402 having a relatively small size. Therefore, an electrical short may be prevented from occurring between the third connection terminals 402 and the second bridge pads 224p2 and between the third connection terminals 402 and the third device pads 412. Accordingly, a semiconductor package may have increased electrical properties and operating stability.

In embodiments that follow, components the same as those discussed with reference to FIGS. 1 to 4 are allocated the same reference numerals thereto, and a repetitive explanation thereof will be omitted or abridged for convenience of description. The following description will focus on differences between the embodiments of FIGS. 1 to 4 and other embodiments described below.

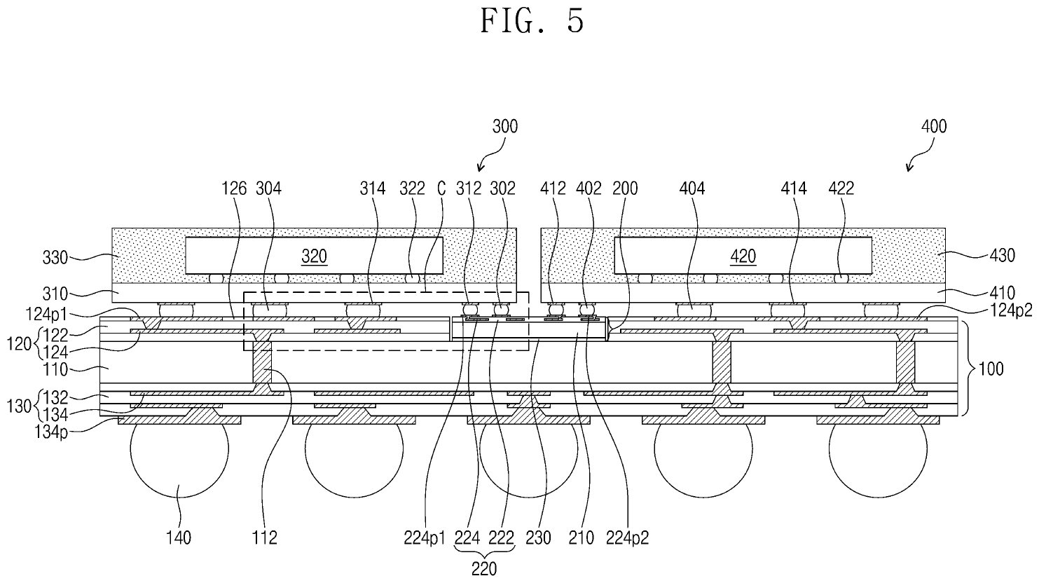

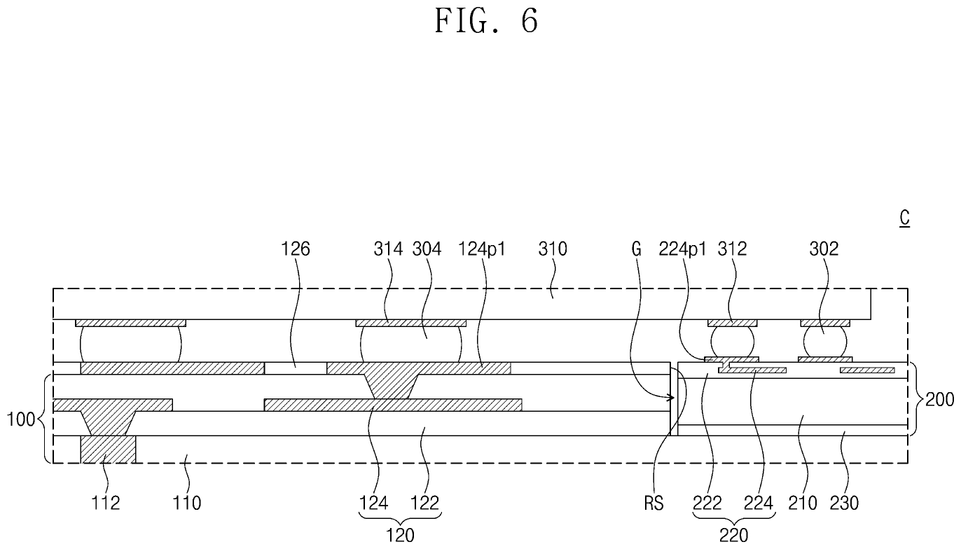

FIG. 5 illustrates a cross-sectional view showing a semiconductor package according to some embodiments of the present inventive concept. FIG. 6 illustrates an enlarged view showing section C of FIG. 5.

Referring to FIGS. 5 and 6, in an embodiment a package substrate 100 may include a core portion 110, an upper buildup portion 120, and a lower buildup portion 130. In an embodiment, the upper buildup portion 120 may include an upper dielectric pattern 122 and an upper wiring pattern 124.

The upper buildup portion 120 may have a recess RS. For example, the recess RS may be shaped like an open hole that connects top and bottom surfaces of the upper buildup portion 120. For example, the recess RS may vertically penetrate the upper dielectric patterns 122 of the upper buildup portion 120 and may expose the top surface of the core portion 110. In an embodiment, the recess RS may be positioned at a central portion of the upper buildup portion 120. In comparison to the recess RS, the upper wiring patterns 124 of the upper buildup portion 120 may be positioned on an outer side of the upper buildup portion 120.

A bridge chip 200 may be disposed on the package substrate 100. The bridge chip 200 may be disposed in the recess RS. The bridge chip 200 may fill only a portion of the recess RS. For example, the bridge chip 200 may be in contact with the top surface of the core portion 110 exposed by the recess RS. The bridge chip 200 may not be in direct contact with at least one inner sidewall of the recess RS or at least one inner lateral surface of the upper buildup portion 120. For example, when viewed in plan, at least one gap G may be present between the upper buildup portion 120 and the bridge chip 200. In an embodiment in which a substrate protection layer 126 is disposed on the upper buildup portion 120, the bridge chip 200 may be spaced apart from the substrate protection layer 126. When viewed in plan, the upper buildup portion 120 may completely surround the bridge chip 200.

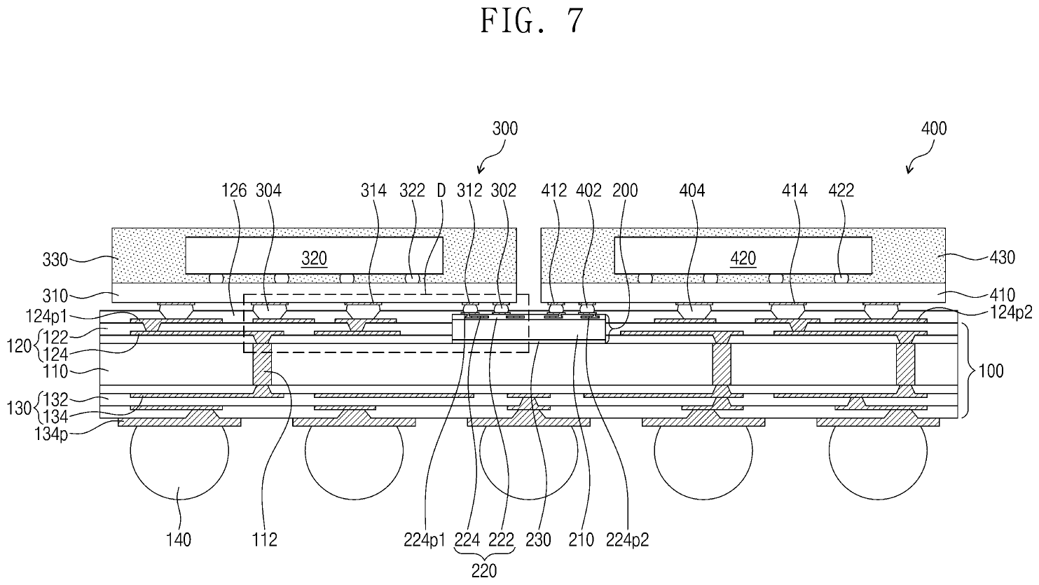

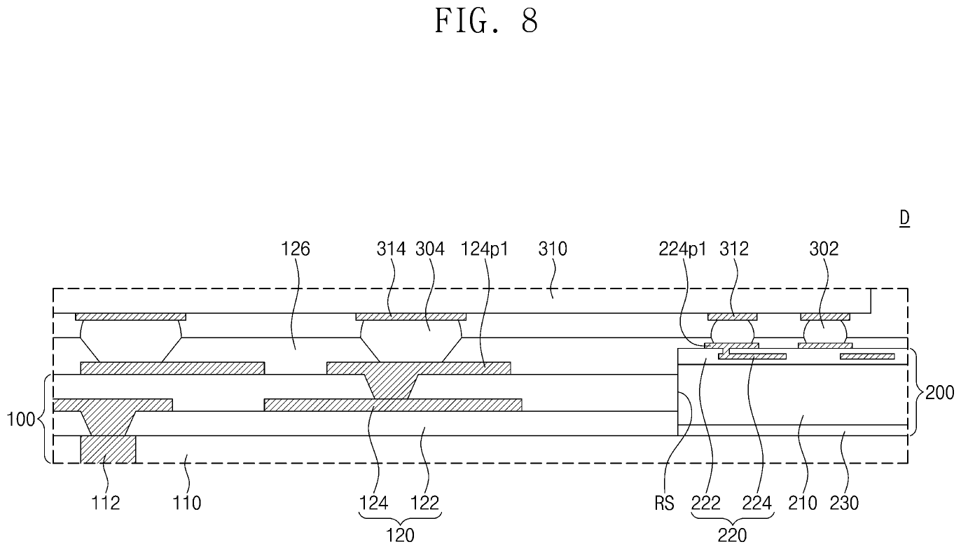

FIG. 7 illustrates a cross-sectional view showing a semiconductor package according to some embodiments of the present inventive concept. FIG. 8 illustrates an enlarged view showing section D of FIG. 7.

Referring to FIGS. 7 and 8, in an embodiment a package substrate 100 may include a core portion 110, an upper buildup portion 120, and a lower buildup portion 130. In an embodiment, the upper buildup portion 120 may include an upper dielectric pattern 122 and an upper wiring pattern 124. The upper buildup portion 120 may have a recess RS. A bridge chip 200 may be disposed on the package substrate 100. The bridge chip 200 may be disposed in the recess RS.

A substrate protection layer 126 may be disposed on the upper buildup portion 120. The substrate protection layer 126 may cover the upper buildup portion 120 and the bridge chip 200. On the package substrate 100, the substrate protection layer 126 may cover the uppermost second wiring layer. For example, the substrate protection layer 126 may cover the upper dielectric pattern 122 and the first and second substrate pads 124p1 and 124p2. On the bridge chip 200, the substrate protection layer 126 may cover the bridge wiring layer 220. For example, the substrate protection layer 126 may cover the bridge dielectric pattern 222, the bridge wiring pattern 224, and the first and second bridge pads 224p1 and 224p2. As the bridge chip 200 has a top surface located at a level higher than that of a top surface of the upper buildup portion 120, a thickness (e.g., in the vertical direction) of the substrate protection layer 126 on the bridge chip 200 may be less than that of the substrate protection layer 126 on the upper buildup portion 120. In an embodiment, the substrate protection layer 126 may penetrate the substrate protection layer 126 to have openings that expose top surfaces of the first and second substrate pads 124p1 and 124p2 and top surfaces of the first and second bridge pads 224p1 and 224p2.

The first, second, third, and fourth connection terminals 302, 304, 402, and 404 may be coupled through the openings to the first and second substrate pads 124p1 and 124p2 and the first and second bridge pads 224p1 and 224p2.

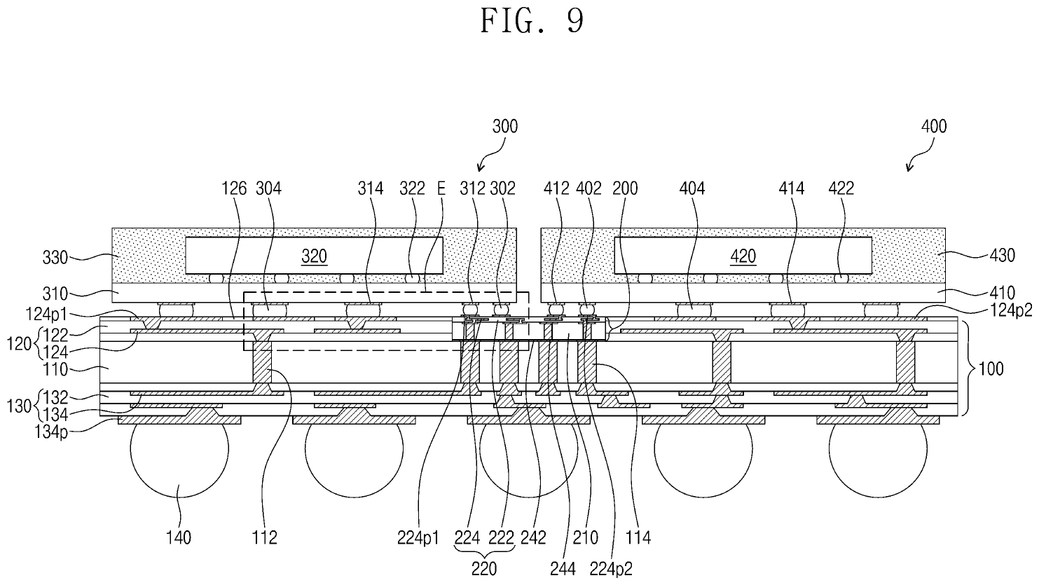

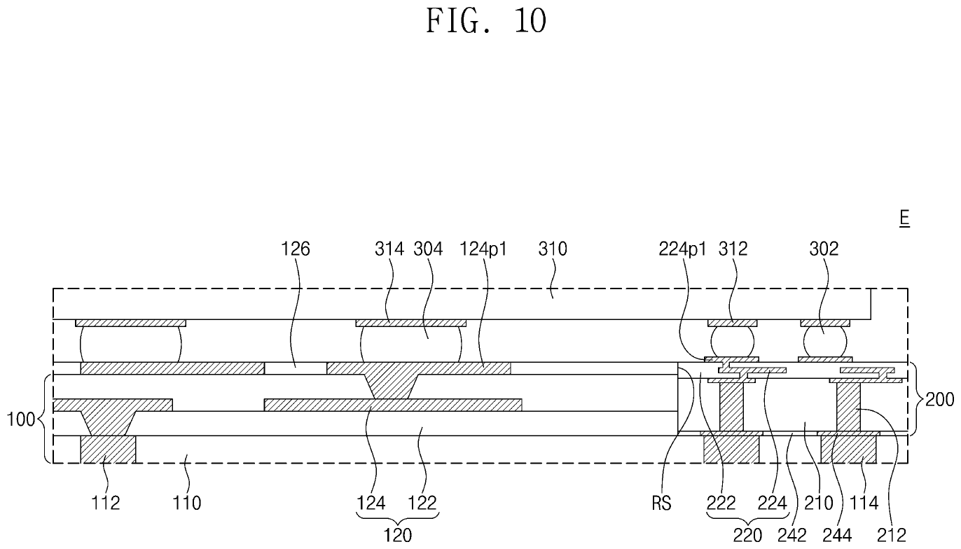

FIG. 9 illustrates a cross-sectional view showing a semiconductor package according to some embodiments of the present inventive concept. FIG. 10 illustrates an enlarged view showing section E of FIG. 9.

Referring to FIGS. 9 and 10, the core portion 110 of the package substrate 100 may further include second vertical connection terminals 114. The second vertical connection terminals 114 may extend from a bottom surface of the core portion 110 towards a top surface of the core portion 110. In an embodiment, the second vertical connection terminals 114 may be exposed on the bottom surface of the core portion 110 and the top surface of the core portion 110. The second vertical connection terminals 114 may electrically connect the bridge chip 200 and the lower buildup portion 130 to each other. The second vertical connection terminals 114 may be positioned below the bridge chip 200. In an embodiment, the second vertical connection terminals 114 may include a metallic material, such as copper (Cu) or tungsten (W).

In an embodiment, the bridge chip 200 may further include chip vias 212, backside pads 244, and a backside protection layer 242.

The chip vias 212 may vertically penetrate the bridge base layer 210 and may be connected to the bridge wiring layer 220. The chip vias 212 may be exposed on a rear surface of the bridge chip 200 or a bottom surface of the bridge base layer 210. The chip vias 212 may include a conductive material. For example, in an embodiment the chip via 212 may include a metallic material, such as copper (Cu) or tungsten (W).

The backside pads 244 may be disposed on the bottom surface of the bridge base layer 210. On the bottom surface of the bridge base layer 210, the backside pads 244 may be correspondingly connected to the chip vias 212. The backside pads 244 may include a conductive material. For example, in an embodiment the backside pads 244 may include a metallic material, such as copper (Cu) or tungsten (W).

The backside protection layer 242 may be disposed on the bottom surface of the bridge base layer 210. The backside protection layer 242 may cover the bottom surface of the bridge base layer 210. The backside protection layer 242 may surround the backside pads 244. In an embodiment, a bottom surface of the backside protection layer 242 may be substantially flat and coplanar with the bottom surface of the backside pads 244. The backside protection layer 242 may include a dielectric material. For example, in an embodiment the backside protection layer 242 may include silicon oxide (SiO), silicon nitride (SiN), or silicon oxynitride (SiON). Alternatively, the backside protection layer 242 may include an adhesive material.

The bridge chip 200 may be disposed on the package substrate 100. The bridge chip 200 may be disposed in the recess RS. The bridge chip 200 may be in contact with the top surface of the core portion 110 exposed by the recess RS. In this embodiment, the backside pads 244 of the bridge chip 200 may be connected to the second vertical connection terminals 114 of the core portion 110. For example, the backside pads 244 and the second vertical connection terminals 114 may be in direct contact with each other on an interface between the bridge chip 200 and the core portion 110. The bridge chip 200 and its connected first and second devices 300 and 400 may be electrically connected to the lower buildup portion 130 through the bridge wiring layer 220, the chip vias 212, the backside pads 244, and the second vertical connection terminals 114.

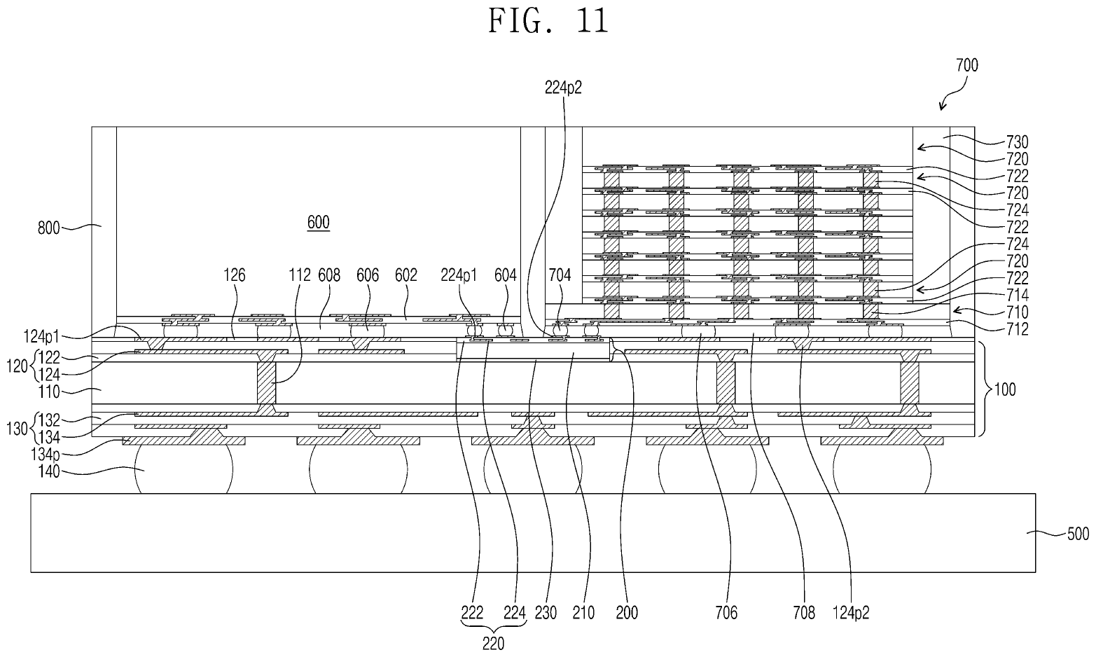

FIG. 11 illustrates a cross-sectional view showing a semiconductor module according to some embodiments of the present inventive concept.

Referring to FIG. 11, a semiconductor package may be a semiconductor module. The semiconductor module may include a module substrate 500, a graphic processing unit 600 and a chip stack 700 that are mounted on the module substrate 500, and an outer molding layer 800 that covers the graphic processing unit 600 and the chip stack 700. The semiconductor module may further include an interposer 100 disposed on the module substrate 500

In an embodiment, the module substrate 500 may include a printed circuit board (PCB) having a signal pattern on a top surface thereof.

In an embodiment, module terminals may be disposed below the module substrate 500. In an embodiment, the module terminals may include solder balls or solder bumps, and based on type of the module terminals, the semiconductor module may be provided in the form of one of a ball grid array (BGA) type, a fine ball-grid array (FBGA) type, and a land grid array (LGA) type. However, embodiments of the present inventive concept are not necessarily limited thereto. For example, in some embodiments, no module terminals may be provided.

The interposer 100 may be disposed on the module substrate 500. The interposer 100 may have a structure that is the same as or similar to that of the package substrate 100 discussed with reference to FIGS. 1 to 10. For example, in an embodiment the interposer 100 may include a core portion 110, an upper buildup portion 120, and a lower buildup portion 130, and the upper buildup portion 120 may have a recess that exposes a top surface of the core portion 110 and is provided with a bridge chip 200 inserted thereinto.

The interposer 100 may redistribute the graphic processing unit 600 and the chip stack 700. In an embodiment, the interposer 100 may be flip-chip mounted on the module substrate 500. For example, the interposer 100 may be mounted on the module substrate 500 through external terminals 140 disposed on external substrate pads 134p. The external terminals 140 may include solder balls or solder bumps. In an embodiment, a first underfill layer may be disposed between the module substrate 500 and the interposer 100.

The graphic processing unit 600 may be disposed on the interposer 100. The graphic processing unit 600 may correspond to the first device 300 discussed with reference to FIGS. 1 to 10. In an embodiment, the graphic processing unit 600 may include a logic circuit. For example, the graphic processing unit 600 may be a logic chip. The graphic processing unit 600 may have a first circuit layer 602 disposed on a bottom surface of the graphic processing unit 600. The first circuit layer 602 may be electrically connected to the logic circuit. First bumps 604 and second bumps 606 may be disposed on the bottom surface of the graphic processing unit 600 or a bottom surface of the first circuit layer 602. The integration of the first bumps 604 may be greater than that of the second bumps 606. For example, the first bumps 604 may have a width and an interval that are less than those of the second bumps 606. The first bumps 604 may be positioned on the bridge chip 200, and the second bumps 606 may be positioned on the upper buildup portion 120. The graphic processing unit 600 may be coupled through the first bumps 604 to the first bridge pads 224p1 of the bridge chip 200, and may be coupled through the second bumps 606 to the first substrate pads 124p1 of the upper buildup portion 120. A second underfill layer 608 may be disposed between the interposer 100 and the graphic processing unit 600. The second underfill layer 608 may surround the first and second bumps 604 and 606, while filling a space between the interposer 100 and the graphic processing unit 600.

The chip stack 700 may be disposed on the interposer 100. The chip stack 700 may correspond to the second device 400 discussed with reference to FIGS. 1 to 10. The chip stack 700 may be disposed to be spaced apart from the graphic processing unit 600. In an embodiment, the graphic processing unit 600 may have a thickness (e.g., in a vertical direction) greater than those of semiconductor chips 710 and 720 of the chip stack 700. A top surface of the chip stack 700 may be located at a level the same as or higher than that of the top surface of the graphic processing unit 600.

In an embodiment, the chip stack 700 may include a base substrate, third semiconductor chips 720 stacked on the base substrate, and a third molding layer 730 that surrounds the third semiconductor chips 720. The following will describe in detail a configuration of the chip stack 700.

The base substrate may be a base semiconductor chip 710. For example, in an embodiment the base substrate may be a wafer-level semiconductor substrate formed of a semiconductor material such as silicon (Si). In the present description, the base semiconductor chip 710 and the base substrate may indicate the same component and may be allocated with the same reference numeral.

In an embodiment, the base semiconductor chip 710 may include a base circuit layer 712 and base through electrodes 714. The base circuit layer 712 may be disposed on a bottom surface of the base semiconductor chip 710. The base circuit layer 712 may include an integrated circuit. For example, the base circuit layer 712 may be a memory circuit. In an embodiment, the base semiconductor chip 710 may be a memory chip, such as a dynamic random access memory (DRAM), a static random access memory (SRAM), a magnetic random access memory (MRAM), or a Flash memory. Alternatively, the base semiconductor chip 710 may be a logic chip. The base through electrodes 714 may penetrate the base semiconductor chip 710 in a direction perpendicular to a top surface of the interposer 100. The base through electrodes 714 may be electrically connected to the base circuit layer 712. The bottom surface of the base semiconductor chip 710 may be an active surface. However, embodiments of the present disclosure are not necessarily limited thereto. For example, in some embodiments, the base substrate may be a wiring substrate that does not include the base semiconductor chip 710.

In an embodiment, the base semiconductor chip 710 may further include a protection layer. The protection layer may be disposed on the bottom surface of the base semiconductor chip 710, thereby covering the base circuit layer 712. The protection layer may include silicon nitride (SiN).

The third semiconductor chip 720 may be mounted on the base semiconductor chip 710. For example, in an embodiment the third semiconductor chip 720 and the base semiconductor chip 710 may constitute a chip-on-wafer (COW) structure. The third semiconductor chip 720 may have a width (e.g., in a horizontal direction) that is less than that of the base semiconductor chip 710.

In an embodiment, the third semiconductor chip 720 may include a second circuit layer 722 and chip through electrodes 724. The second circuit layer 722 may include a memory circuit. For example, in some embodiments the third semiconductor chip 720 may be a memory chip, such as a dynamic random access memory (DRAM), a static random access memory (SRAM), a magnetic random access memory (MRAM), or a Flash memory. In an embodiment, the second circuit layer 722 may include the same circuit as that of the base circuit layer 712. However, embodiments of the present inventive concept are not necessarily limited thereto. The chip through electrodes 724 may penetrate the third semiconductor chip 720 in a direction perpendicular to the top surface of the interposer 100. The chip through electrodes 724 may be electrically connected to the second circuit layer 722. The third semiconductor chip 720 may have a bottom surface as an active surface.

The third semiconductor chip 720 may be coupled to the base semiconductor chip 710. For example, pads of the second circuit layer 722 of the third semiconductor chip 720 may be in direct contact with top surfaces of the base through electrodes 714 exposed on the top surface of the base semiconductor chip 710. Alternatively, the third semiconductor chip 720 may be mounted on the top surfaces of the base through electrodes 714 through terminals provided on the pads of the second circuit layer 722.

In an embodiment, the third semiconductor chip 720 may be provided in plural. For example, a plurality of third semiconductor chips 720 may be stacked on the base semiconductor chip 710. In an embodiment, the number of stacked third semiconductor chips 720 may be in a range of about 8 to about 32. However, embodiments of the present inventive concept are not necessarily limited thereto. An uppermost third semiconductor chip 720 may not include the chip through electrodes 724. In addition, in an embodiment the uppermost third semiconductor chip 720 may have a thickness (e.g., in the vertical direction) greater than those of other underlying third semiconductor chips 720.

Adjacent third semiconductor chips 720 may be bonded to each other. For example, the pads of the second circuit layer 722 of each of the third semiconductor chips 720 may be in direct contact with top surfaces of the chip through electrodes 724 exposed on a top surface of an underlying third semiconductor chip 720. Alternatively, the third semiconductor chips 720 may be mounted on the top surfaces of the chip through electrodes 724 through terminals disposed on the pads of the second circuit layer 722.

A third molding layer 730 may be disposed on a top surface of the base semiconductor chip 710. The third molding layer 730 may cover the base semiconductor chip 710 and may surround the third semiconductor chips 720. In an embodiment, the third molding layer 730 may have a top surface coplanar with that of the uppermost third semiconductor chip 720 (e.g., in the vertical direction), and the uppermost third semiconductor chip 720 may be exposed from the third molding layer 730. The third molding layer 730 may include a dielectric polymer material. For example, in an embodiment the third molding layer 730 may include an epoxy molding compound (EMC).

The chip stack 700 may be provided as discussed above.

Third bumps 704 and fourth bumps 706 may be disposed on a bottom surface of the chip stack 700 or a bottom surface of the base circuit layer 712. The integration of the third bumps 704 may be greater than that of the fourth bumps 706. For example, the third bumps 704 may have a width and an interval less than those of the fourth bumps 706. The third bumps 704 may be positioned on the bridge chip 200, and the fourth bumps 706 may be positioned on the upper buildup portion 120. The chip stack 700 may be coupled through the third bumps 704 to the second bridge pads 224p2 of the bridge chip 200, and the fourth bumps 706 may be coupled through the fourth bumps 706 to the second substrate pads 124p2 of the upper buildup portion 120. A third underfill layer 708 may be disposed between the interposer 100 and the chip stack 700. The third underfill layer 708 may surround the third and fourth bumps 704 and 706, while filling a space between the interposer 100 and the chip stack 700.

The outer molding layer 800 may be disposed on the interposer 100. The outer molding layer 800 may cover the top surface of the interposer 100. The outer molding layer 800 may surround the graphic processing unit 600 and the chip stack 700. In an embodiment, the outer molding layer 800 may have a top surface located at a level (e.g., in the vertical direction) the same as that of the top surface of the chip stack 700. The outer molding layer 800 may include a dielectric material. For example, in an embodiment the outer molding layer 800 may include an epoxy molding compound (EMC).

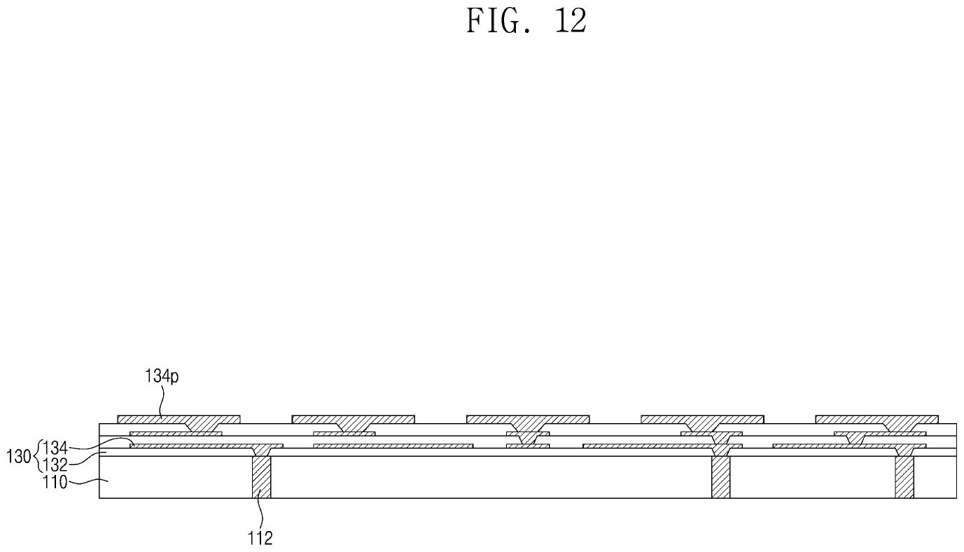

FIGS. 12 to 18 illustrate cross-sectional views showing a method of fabricating a semiconductor package according to some embodiments of the present inventive concept.

Referring to FIG. 12, a core portion 110 may be provided. First vertical connection terminals 112 may be formed in the core portion 110. For example, in an embodiment the first vertical connection terminals 112 may be formed by forming holes that penetrate the core portion 110 (e.g., penetrate an entire thickness of the core portion 110 in the vertical direction), and then filling the holes with a conductive material.

A lower buildup portion 130 may be formed on the core portion 110. For example, in an embodiment a dielectric layer may be formed on a top surface of the core portion 110, and then the dielectric layer may be patterned to form one lower dielectric pattern 132. A conductive layer may be formed on the lower dielectric pattern 132, and then the conductive layer may be patterned to form one lower wiring pattern 134. The processes for forming the lower dielectric pattern 132 and the lower wiring pattern 134 may be repeatedly performed. A plurality of lower dielectric patterns 132 and a plurality of lower wiring patterns 134 may constitute the lower buildup portion 130 discussed with reference to FIG. 1.

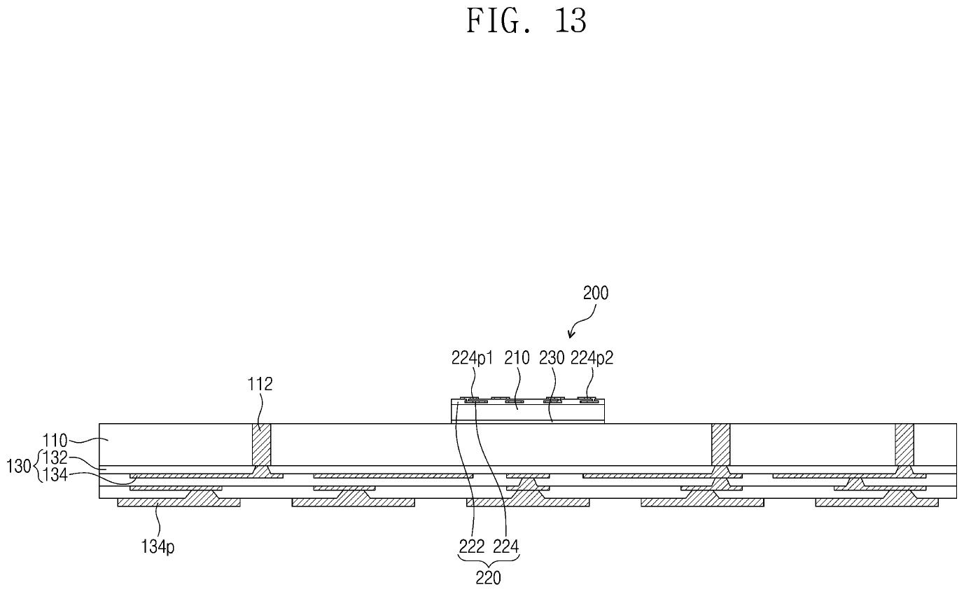

Referring to FIG. 13, a resultant structure of FIG. 12 may be overturned (e.g., inverted 180 degrees). Therefore, the lower buildup portion 130 may be positioned below the core portion 110.

A bridge chip 200 may be attached to the core portion 110. The bridge chip 200 may be the same as or similar to the bridge chip 200 discussed with reference to FIGS. 1 to 10. In an embodiment, the bridge chip 200 may be attached through an adhesion layer 230 to the core portion 110. For example, in an embodiment the adhesion layer 230 may be attached to (e.g., attached directly thereto) a rear surface of a bridge base layer 210 of the bridge chip 200, and then the bridge chip 200 may be attached to the top surface of the core portion 110 via the adhesion layer 230. When viewed in plan, the bridge chip 200 may be positioned between the first vertical connection terminals 112 (e.g., in a horizontal direction).

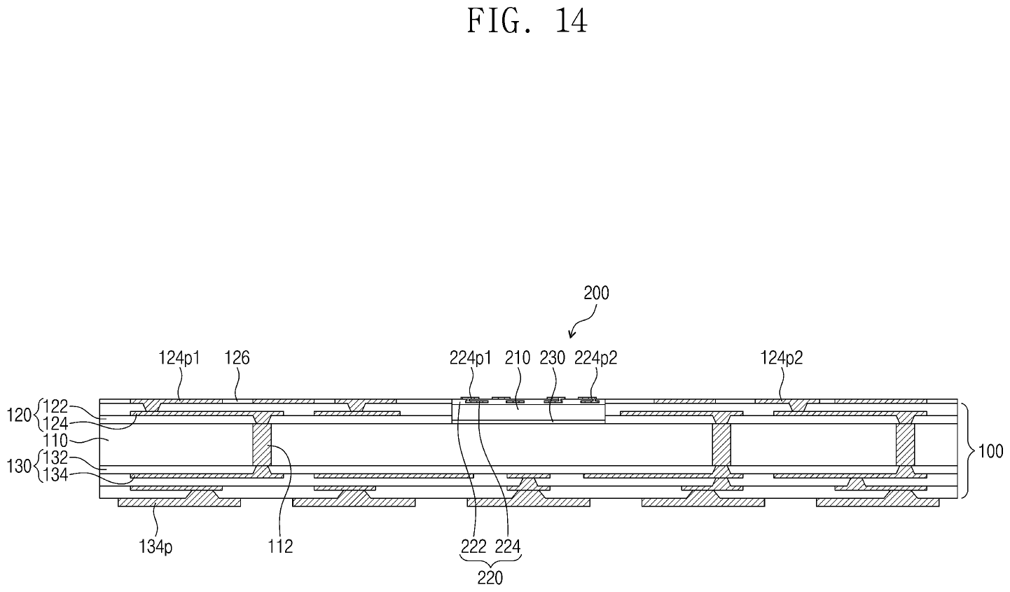

Referring to FIG. 14, an upper buildup portion 120 may be formed on the core portion 110. For example, in an embodiment a dielectric layer may be formed on the top surface of the core portion 110, and the dielectric layer may be patterned to form one upper dielectric pattern 122. A conductive layer may be formed on the upper dielectric pattern 122, and then the conductive layer may be patterned to form one upper wiring pattern 124. The processes for forming the upper dielectric pattern 122 and the upper wiring pattern 124 may be repeatedly performed. A plurality of upper dielectric patterns 122 and a plurality of upper wiring patterns 124 may constitute the upper buildup portion 120 discussed with reference to FIG. 1. The upper buildup portion 120 may be formed to surround the bridge chip 200. In an embodiment, the upper buildup portion 120 may be in direct contact with at least one lateral surface of the bridge chip 200. For example, as shown in an embodiment of FIG. 14, the upper buildup portion 120 may be in direct contact with both lateral surfaces of the bridge chip 200. The upper buildup portion 120 may include first and second substrate pads 124p1 and 124p2 having top surfaces that are located at a level (e.g., in the vertical direction) that is lower than that of top surfaces of the first and second bridge pads 224p1 and 224p2 of the bridge chip 200. A package substrate 100 may be constituted by the core portion 110, the upper buildup portion 120, and the lower buildup portion 130.

In an embodiment, a substrate protection layer 126 may be formed on the upper buildup portion 120 to surround the first and second substrate pads 124p1 and 124p2. The first and second substrate pads 124p1 and 124p2 may be exposed on a top surface of the substrate protection layer 126.

FIGS. 13 and 14 depict that the bridge chip 200 is attached on the core portion 110, and then the upper buildup portion 120 is formed. However, embodiments of the present inventive concept are not necessarily limited thereto. According to some embodiments, the upper buildup portion 120 may be formed in advance on the core portion 110.

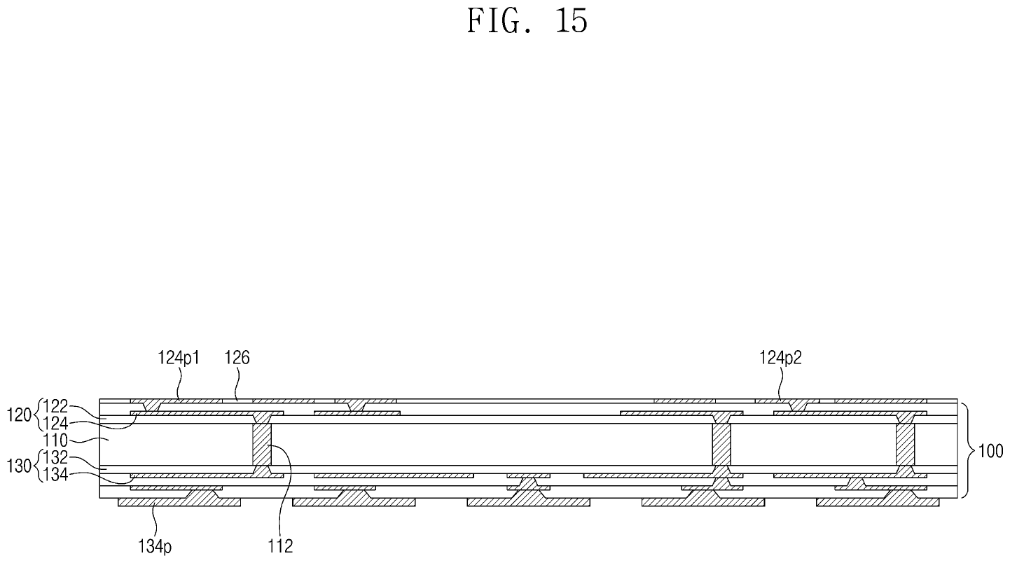

Referring to FIG. 15, on a resultant structure of FIG. 12, the upper buildup portion 120 may be formed on the core portion 110. For example, in an embodiment a dielectric layer may be formed on the top surface of the core portion 110, and the dielectric layer may be patterned to form one upper dielectric pattern 122. A conductive layer may be formed on the upper dielectric pattern 122, and then the conductive layer may be patterned to form one upper wiring pattern 124. The processes for forming the upper dielectric pattern 122 and the upper wiring pattern 124 may be repeatedly performed. A plurality of upper dielectric patterns 122 and a plurality of upper wiring patterns 124 may constitute the upper buildup portion 120 discussed with reference to FIG. 1.

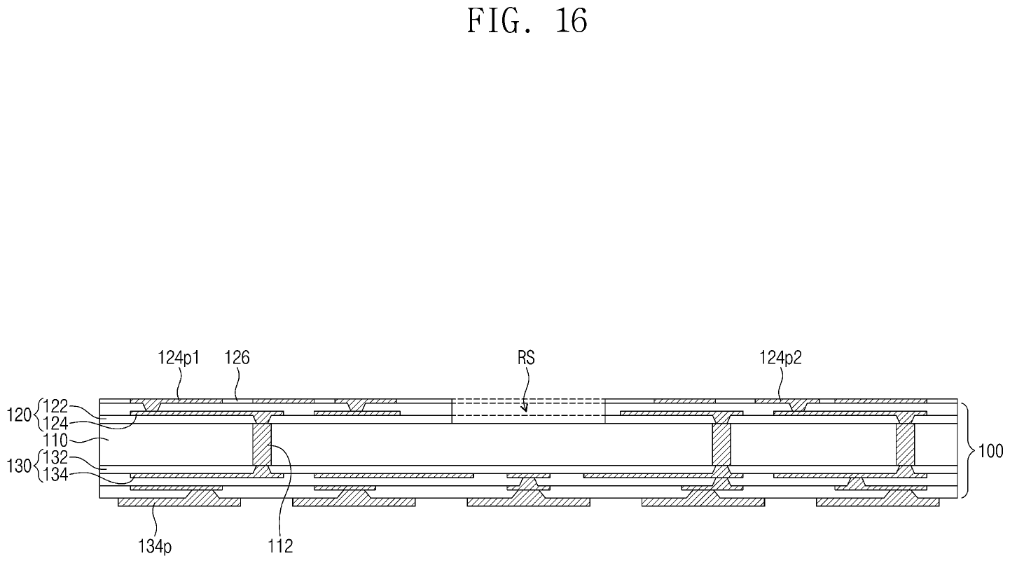

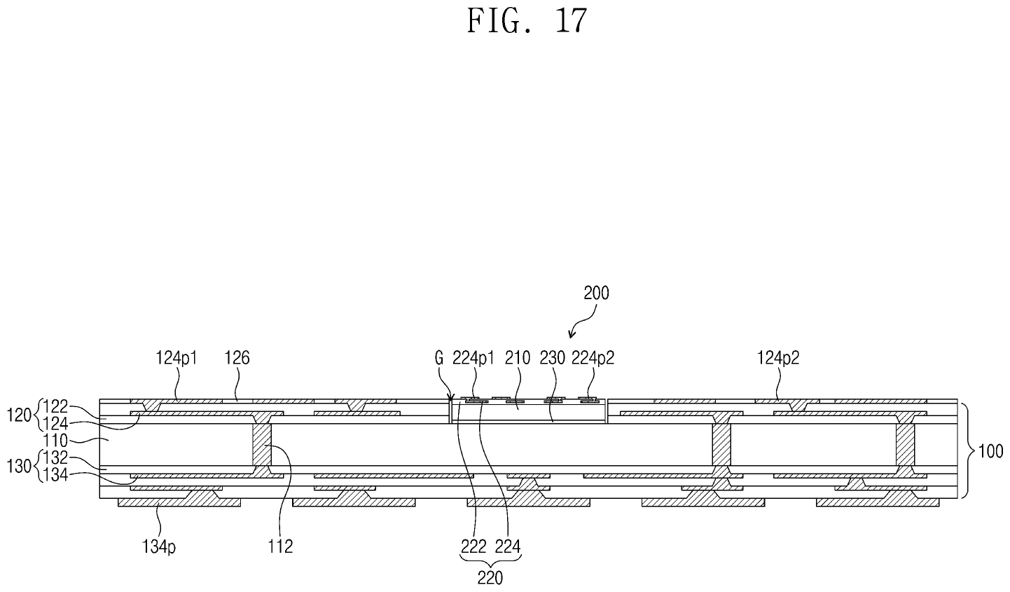

Referring to FIG. 16, the upper buildup portion 120 may be patterned to form a recess RS. For example, the upper dielectric patterns 122 of the upper buildup portion 120 may be etched to expose the top surface of the core portion 110. The recess RS may define an area where a bridge chip (see 200 of FIG. 17) will be formed in a subsequent process. When viewed in plan, the recess RS may have a size that is greater than that of the bridge chip 200 which is intended to be attached in the recess RS. For example, the recess RS may have a width greater than that of the bridge chip 200.

Referring to FIG. 17, a bridge chip 200 may be attached onto the core portion 110. The bridge chip 200 may be disposed in the recess RS. In an embodiment, the bridge chip 200 may be attached through an adhesion layer 230 to the core portion 110. For example, the adhesion layer 230 may be attached to a rear surface of the bridge base layer 210 of the bridge chip 200, and then the bridge chip 200 may be attached to a bottom surface of the recess RS or the top surface of the core portion 110 which is exposed by the recess RS. When viewed in plan, the bridge chip 200 may be positioned between the first vertical connection terminals 112. In an embodiment, the bridge chip 200 may be spaced apart from at least one inner sidewall of the recess RS. For example, a gap G may be present between the upper buildup portion 120 and the bridge chip 200. In this embodiment, a semiconductor package may be fabricated which is discussed with reference to FIGS. 5 and 6. The following will discuss an embodiment of FIGS. 13 and 14.

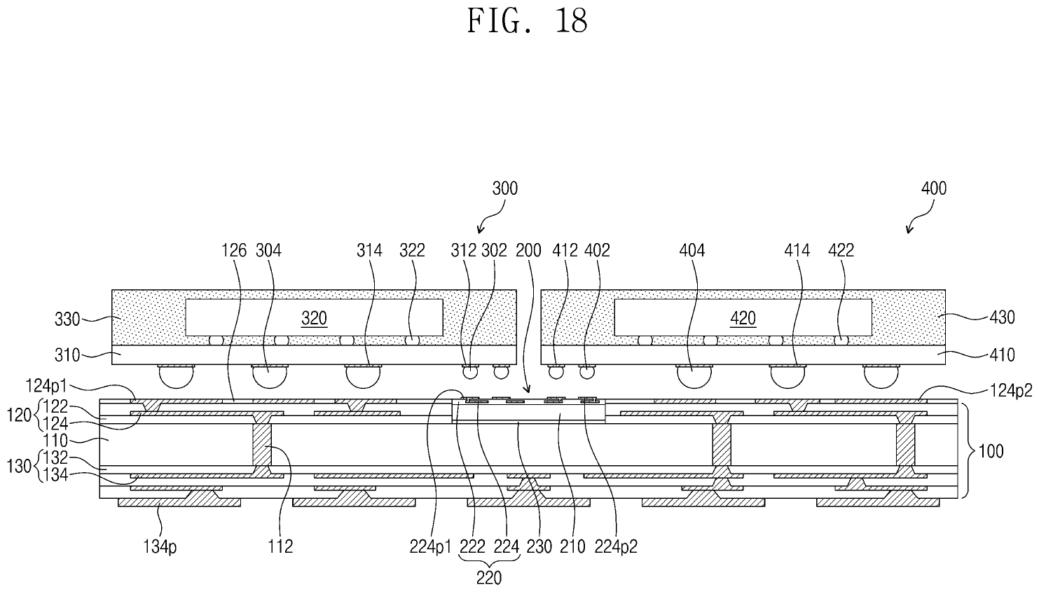

Referring to FIG. 18, a first device 300 and a second device 400 may be disposed on the package substrate 100. For example, in an embodiment the first and second devices 300, 400 may be disposed directly on an upper surface of the package substrate 100.

The first device 300 may be the same as or similar to the first device 300 discussed with reference to FIGS. 1 to 10. For example, in an embodiment the first device 300 may include a first substrate 310, a first semiconductor chip 320, and a first molding layer 330. The first substrate 310 may include first and second device pads 312 and 314 disposed on a bottom surface of the first substrate 310. The integration of the first device pads 312 may be greater than that of the second device pads 314. For example, the first device pads 312 may have a width and an interval that are less than those of the second device pads 314. First connection terminals 302 may be provided on the first device pads 312. Second connection terminals 304 may be provided on the second device pads 314. A size of the first connection terminals 302 provided on the first device pads 312 having a small width may be less than that of the second connection terminals 304 provided on the second device pads 314 having a large width. For example, the first connection terminals 302 may have a width and a height less than those of the second connection terminals 304.

The second device 400 may be the same as or similar to the second device 400 discussed with reference to FIGS. 1 to 10. For example, the second device 400 may include a second substrate 410, a second semiconductor chip 420, and a second molding layer 430. The second substrate 410 may include third and fourth device pads 412 and 414 disposed on a bottom surface of the second substrate 410. The integration of the third device pads 412 may be greater than that of the fourth device pads 414. For example, the third device pads 412 may have a width and an interval less than those of the fourth device pads 414. Third connection terminals 402 may be provided on the third device pads 412. Fourth connection terminals 404 may be provided on the fourth device pads 414. A size of the third connection terminals 402 provided on the third device pads 412 having a small width may be less than that of the fourth connection terminals 404 provided on the fourth device pads 414 having a large width. For example, the third connection terminals 402 may have a width and a height that is less than those of the fourth connection terminals 404.

Referring back to FIG. 1, the first device 300 may be mounted on the package substrate 100. The first device 300 may be placed on the package substrate 100. For example, the first device 300 may be aligned on the package substrate 100 to allow the first device pads 312 to be disposed on the first bridge pads 224p1 and to allow the second device pads 314 to be disposed on the first substrate pads 124p1. The first device 300 may approach the package substrate 100 to cause the first connection terminals 302 to directly contact the first bridge pads 224p1 and to cause the second connection terminals 304 to directly contact the first substrate pads 124p1. As the top surface of the first bridge pads 224p1 is located at a level higher than that of the top surface of the first substrate pads 124p1, even though the first connection terminals 302 have a size less than that of the second connection terminals 304, the first connection terminals 302 may easily directly contact the first bridge pads 224p1. Afterwards, a soldering process may be performed on the first and second connection terminals 302 and 304, such that the first connection terminals 302 may connect the first device pads 312 to the first bridge pads 224p1, and the second connection terminals 304 may connect the second device pads 314 to the first substrate pads 124p1.

According to some embodiments of the present inventive concept, even though the first device 300 is provided with the first and second connection terminals 302 and 304 having different sizes from each other, a difference in height of pads between the bridge chip 200 and the upper buildup portion 120 of the package substrate 100 may be used to achieve an electrical connection between the package substrate 100 and the first device 300. Thus, it may possible to prevent the occurrence of an electrical short between the first device 300 and the bridge chip 200, to provide a method of fabricating a semiconductor package with less occurrence of failure, and to accomplish a semiconductor package with increased electrical connection.

The second device 400 may be mounted on the package substrate 100. The second device 400 may be placed on the package substrate 100. For example, the second device 400 may be aligned on the package substrate 100 to allow the third device pads 412 to be disposed on the second bridge pads 224p2 and to allow the fourth device pads 414 to be disposed on the second substrate pads 124p2. The second device 400 may approach the package substrate 100 to cause the third connection terminals 402 to directly contact the second bridge pads 224p2 and to cause the fourth connection terminals 404 to directly contact the second substrate pads 124p2. As the top surface of the second bridge pads 224p2 is located at a level higher than that of the top surface of the second substrate pads 124p2, even though the third connection terminals 402 have their size less than that of the fourth connection terminals 404, the third connection terminals 402 may easily directly contact the second bridge pads 224p2. Afterwards, a soldering process may be performed on the third and fourth connection terminals 402 and 404, such that the third connection terminals 402 may connect the third device pads 412 to the second bridge pads 224p2, and the fourth connection terminals 404 may connect the fourth device pads 414 to the second substrate pads 124p2.

According to some embodiments of the present inventive concept, even though the second device 400 is provided with the third and fourth connection terminals 402 and 404 having different sizes from each other, it may be possible to prevent the occurrence of electrical short between the second device 400 and the bridge chip 200, to provide a method of fabricating a semiconductor package with less occurrence of failure, and to accomplish a semiconductor package with increased electrical connection.

External terminals 140 may be formed on a bottom surface of the package substrate 100. For example, the external terminals 140 may be attached to external substrate pads 134p provided on the a bottom surface of the lower buildup portion 130.

In a semiconductor package according to some embodiments of the present inventive concept, an electrical connection through a bridge chip may be provided on an area where a wiring connection with high integration is required, and an electrical connection through a package substrate may be provided on an area where a wiring connection with low integration is required. It may thus be possible to provide a package substrate having high integration and a semiconductor package including the package substrate. In addition, as a bridge chip is used only on an area having high integration, a semiconductor package may have a reduced manufacturing cost.

Moreover, an interval between bridge pads and device pads is less than that between substrate pads and device pads, and thus the bridge pads and the device pads may be connected even through connection terminals having sizes that are relatively small. For example, although connection terminals having relatively large sizes are provided between the package substrate and a device mounted on the package substrate, a small interval may be provided between the bridge chip and the device, and an electrical short may be prevented from occurring between the bridge pads and the device pads. Accordingly, a semiconductor package may have increased electrical properties and operating stability.

Although the present inventive concept have been described in connection with some non-limiting embodiments of the present inventive concept illustrated in the accompanying drawings, it will be understood by one of ordinary skill in the art that variations in form and detail may be made therein without departing from the spirit and essential features of the present inventive concept. The above-described embodiments should thus be considered illustrative and not restrictive.

What is claimed is:

1. A semiconductor package, comprising:
a package substrate;
a first device on the package substrate; and
a second device on the package substrate, the second device is horizontally spaced apart from the first device,
wherein the package substrate includes:
a core portion;
a bridge chip on a top surface of the core portion, the bridge chip having first pads; and
an upper buildup portion that covers the top surface of the core portion and surrounds the bridge chip, the upper buildup portion having second pads,
wherein first solders couple the first device to the first pads of the bridge chip and second solders couple the first device to the second pads of the upper buildup portion,
wherein a first height of the first solders is less than a second height of the second solders, and
wherein a first interval between adjacent first solders of the first solders is less than a second interval between adjacent second solders of the second solders.

2. The semiconductor package of claim 1, wherein a top surface of the first pads is positioned at a level higher than a level of a top surface of the second pads.

3. The semiconductor package of claim 1, wherein a first interval between the first device and the bridge chip is less than a second interval between the first device and the upper buildup portion.

4. The semiconductor package of claim 1, wherein a top surface of the bridge chip is exposed from a top surface of the upper buildup portion.

5. The semiconductor package of claim 1, wherein:
the bridge chip further includes third pads and the upper buildup portion further includes fourth pads;
third solders couple the second device to the third pads of the bridge chip and fourth solders couple the second device to the fourth pads of the upper buildup portion,
a third height of the third solders is less than a fourth height of the fourth solders, and
a third interval between adjacent third solders of the third solders is less than a fourth interval between adjacent fourth solders of the fourth solders.

6. The semiconductor package of claim 5, wherein a top surface of the third pads is positioned at a level higher than a level of a top surface of the fourth pads.

7. The semiconductor package of claim 5, wherein an interval between the second device and the bridge chip is less than an interval between the second device and the upper buildup portion.

8. The semiconductor package of claim 1, wherein a lateral surface of the bridge chip is in direct contact with the upper buildup portion.

9. The semiconductor package of claim 1, wherein the core portion includes first vias that vertically penetrate the core portion,
wherein the first vias are electrically connected to the upper buildup portion.

10. The semiconductor package of claim 9, wherein:
the core portion further includes second vias disposed below the bridge chip and vertically penetrating the core portion;
the bridge chip includes fifth pads on a bottom surface of the bridge chip; and
the second vias are coupled to the fifth pads of the bridge chip.

11. The semiconductor package of claim 1, wherein an adhesion layer attaches the bridge chip to the top surface of the core portion.

12. The semiconductor package of claim 1, wherein:
the first device includes a logic chip;
the second device includes a chip stack; and
wherein the chip stack includes:
a base chip;
a plurality of memory chips on the base chip; and
a molding layer on the base chip, the molding layer surrounding the memory chips.

13. A semiconductor package, comprising:
a package substrate;
a first device on the package substrate; and
a second device on the package substrate, the second device is horizontally spaced apart from the first device,
wherein the package substrate includes:
a core portion;
a bridge chip on a top surface of the core portion; and
an upper buildup portion that covers the top surface of the core portion and surrounds the bridge chip,
wherein the bridge chip includes first pads below the first device and second pads below the second device,
wherein the upper buildup portion includes third pads below the first device and fourth pads below the second device, and
wherein top surfaces of the first and second pads are positioned at a level higher than a level of top surfaces of the third and fourth pads.

14. The semiconductor package of claim 13, wherein:
first connection terminals couple the first device to the first pads and second connection terminals couple the first device to the third pads;
a first height of the first connection terminals is less than a second height of the second connection terminals; and
a first interval between adjacent first connection terminals of the first connection terminals is less than a second interval between adjacent second connection terminals of the second connection terminals.

15. The semiconductor package of claim 14, wherein:
third connection terminals couple the second device to the second pads and fourth connection terminals couple the second device to the fourth pads;
a third height of the third connection terminals is less than a fourth height of the fourth connection terminals, and
a third interval between adjacent third connection terminals of the third connection terminals is less than a fourth interval between adjacent fourth connection terminals of the fourth connection terminals.

16. The semiconductor package of claim 13, wherein:
an interval between the first device and the bridge chip is less than an interval between the first device and the upper buildup portion; and
an interval between the second device and the bridge chip is less than an interval between the second device and the upper buildup portion.

17. The semiconductor package of claim 13, wherein a top surface of the bridge chip is exposed from a top surface of the upper buildup portion.

18. The semiconductor package of claim 13, wherein an adhesion layer attaches the bridge chip to the top surface of the core portion.

19. The semiconductor package of claim 13, wherein a lateral surface of the bridge chip is in direct contact with the upper buildup portion.

20. A semiconductor package, comprising:
a substrate;
a first semiconductor chip on the substrate;
a chip stack horizontally spaced apart from the first semiconductor chip on the substrate, the chip stack including vertically stacked second semiconductor chips; and
a molding layer on the substrate, the molding layer surrounding the first semiconductor chip and the chip stack,
wherein the substrate includes:
a core portion;
a bridge chip on a top surface of the core portion, the bridge chip having first pads; and
an upper buildup portion that covers the top surface of the core portion and surrounds the bridge chip, the upper buildup portion having second pads,
wherein first connection terminals couple the first semiconductor chips to the first pads and the second pads,
wherein second connection terminals couple the chip stack to the first pads and the second pads,
wherein an interval between adjacent first pads of the first pads is less than an interval between adjacent second pads of the second pads,
wherein a vertical distance between the first semiconductor chips and the first pads is less than a vertical distance between the first semiconductor chip and the second pads, and
wherein a vertical distance between the chip stack and the first pads is less than a vertical distance between the chip stack and the second pads.
